(19) United States
(12) Patent Application Publication
(10) Pub. No.: US 2025/0248252 A1
(43) Pub. Date: Jul. 31, 2025

(54) DISPLAY DEVICE AND ELECTRONIC DEVICE INCLUDING THE SAME

(71) Applicant: Samsung Display Co., LTD., Yongin-si (KR)

(72) Inventors: SEUNG-JUN LEE, Yongin-si (KR); JAEWOO LEE, Yongin-si (KR); TAE-HO KIM, Yongin-si (KR); KWANGWOO PARK, Yongin-si (KR); SANG MIN JEON, Yongin-si (KR)

(73) Assignee: Samsung Display Co., LTD., Yongin-si (KR)

(21) Appl. No.: 19/010,373

(22) Filed: Jan. 6, 2025

(30) Foreign Application Priority Data
Jan. 26, 2024 (KR) 10-2024-0011990

(51) Int. Cl. H10K 59/131; G09G 3/3258

(52) U.S. Cl. CPC H10K 59/131; G09G 3/3258; G09G 2300/0819; G09G 2300/0852; G09G 2300/0861

(57) ABSTRACT

A display device includes a plurality of data lines disposed in a display area and extending in a first direction, a plurality of gate lines disposed in the display area and extending in a second direction intersecting the first direction, a plurality of bypass data lines electrically connected to the plurality of data lines and disposed in a first peripheral area adjacent to the display area, and a plurality of bypass gate lines electrically connected to the plurality of gate lines, disposed in the first peripheral area, and alternately disposed in at least two layers.

### CROSS-REFERENCE TO RELATED APPLICATION(S)

This application claims priority to and benefits of Korean Patent Application No. 10-2024-0011990 under 35 U.S.C. § 119, filed on Jan. 26, 2024, in the Korean Intellectual Property Office (KIPO), the entire contents of which are incorporated herein by reference.

### BACKGROUND

### 1. Technical Field

The disclosure relates to a display device that provides visual information and an electronic device including the same.

### 2. Description of the Related Art

A display device includes a display area where an image is displayed and a non-display area disposed outside the display area. Pixels for displaying images and wires connected to the pixels are disposed in the display area. In the non-display area, drivers for driving the pixels and functional modules such as camera modules and sensor modules are disposed.

Recently, a hole may be formed inside the display area to reduce dead space caused by the non-display area. A functional module may be disposed on the back of the display device to correspond to the hole, and the functional module may detect or recognize an object, user, etc. disposed in a front of the display device through the hole. In case that the hole is formed inside the display area, the wires disposed in the display area may bypass the hole. Accordingly, the wires are disposed adjacent to an edge of the hole, so that no image is displayed, and a peripheral area surrounding the hole may be formed.

### SUMMARY

The disclosure provides a display device with improved display quality and an electronic device including the same.

A display device according to an embodiment of the disclosure may include a plurality of data lines disposed in a display area and extending in a first direction, a plurality of gate lines disposed in the display area and extending in a second direction intersecting the first direction, a plurality of bypass data lines electrically connected to the plurality of data lines and disposed in a first peripheral area adjacent to the display area, and a plurality of bypass gate lines electrically connected to the plurality of gate lines, disposed in the first peripheral area, and alternately disposed in at least two layers.

In an embodiment, the display area may include a first pixel, a second pixel spaced apart from the first pixel in the second direction, a third pixel spaced apart from the first pixel in a direction opposite to the first direction, and a fourth pixel spaced apart from the third pixel in the second direction, and the plurality of gate lines may include a first gate line electrically connected to the first pixel and extending in the second direction, a second gate line electrically connected to the second pixel and extending in the second direction, a third gate line electrically connected to the third pixel and extending in the second direction, a fourth gate line electrically connected to the fourth pixel and extending in the second direction, a fifth gate line electrically connected to the first, second, third, and fourth pixels and extending in the second direction and a sixth gate line electrically connected to the first, second, third, and fourth pixels and extending in the second direction.

In an embodiment, the plurality of bypass gate lines may include a first, a second, a third, a fourth, a fifth, and a sixth bypass gate lines electrically connected to the first, second, third, fourth, fifth, and sixth gate lines respectively and disposed in the first peripheral area, and the first, second, fifth, third, fourth, and sixth bypass gate lines may be alternately disposed in the at least two layers.

In an embodiment, the first, fourth, and fifth bypass gate lines and the second, third, and sixth bypass gate lines may be disposed on different layers.

In an embodiment, the first gate line may be spaced apart from the fifth gate line by a gap in a range of about 2 μm to about 3.5 μm.

In an embodiment, one of the plurality of data lines may be electrically connected to the first, second, third, and fourth pixels.

In an embodiment, the display device may further include a first gate driver electrically connected to the first and third gate lines, a second gate driver electrically connected to the second and fourth gate lines, a third gate driver electrically connected to the fifth gate line, and a fourth gate driver electrically connected to the sixth gate line. The first and third gate drivers may be disposed on a side of a second peripheral area, and the second and fourth gate drivers may be disposed on another side of the second peripheral area to be spaced apart from the side of the second peripheral area in the second direction with the display area interposed between the side and the another side of the second peripheral area. In an embodiment, the plurality of bypass data lines may be disposed on the

plurality of bypass gate lines.

In an embodiment, the plurality of bypass data lines may be disposed on a same layer.

In an embodiment, the display device may further include a driving voltage line disposed between the plurality of bypass data lines and the plurality of bypass gate lines in a cross-sectional view. The driving voltage line may overlap the plurality of bypass gate lines in a plan view.

In an embodiment, the first peripheral area may be disposed between the display area and a hole area.

In an embodiment, the display area may include a first pixel, a second pixel spaced apart from the first pixel in the second direction, a third pixel spaced apart from the first pixel in a direction opposite to the first direction, and a fourth pixel spaced apart from the third pixel in the second direction, and the plurality of gate lines may include a first gate line electrically connected to the first pixel and extending in the second direction, a second gate line electrically connected to the second pixel and extending in the second direction, a third gate line electrically connected to the third pixel and extending in the second direction, a fourth gate line electrically connected to the fourth pixel and extending in the second direction, a fifth gate line electrically connected to the first, second, third, and fourth pixels and extending in the second direction, a sixth gate line electrically connected to the first, second, third, and fourth pixels and extending in the second direction, a seventh gate line electrically connected to the first, second, third, and fourth pixels and extending in the second direction and an eighth gate line electrically connected to the first, second, third, and fourth pixels and extending in the second direction.

In an embodiment, the plurality of bypass gate lines may include a first, a second, a third, a fourth, a fifth, a sixth, a seventh, and a eighth bypass gate lines electrically connected to the first, second, third, fourth, fifth, sixth, seventh, and eighth gate lines respectively and disposed in the first peripheral area, and the first, fifth, second, sixth, third, seventh, fourth, and eighth bypass gate lines may be alternately disposed in the at least two layers.

In an embodiment, the first, second, third, and fourth gate lines and the fifth, sixth, seventh, and eighth gate lines may be alternately disposed on different layers.

In an embodiment, the first gate line may be spaced apart from the second gate line by a gap in a range of about 2 μm to about 3.5 μm.

In an embodiment, one of the plurality of data lines may be electrically connected to the first, second, third, and fourth pixels.

In an embodiment, the display device may further include a first gate driver electrically connected to the first and third gate lines, a second gate driver electrically connected to the second and fourth gate lines, a third gate driver electrically connected to the fifth gate line, a fourth gate driver electrically connected to the sixth gate line, a fifth gate driver electrically connected to the seventh gate line, and a sixth gate driver electrically connected to the eighth gate line. The first, third, and fifth gate drivers may be disposed on a side of a second peripheral area, and the second, fourth, and sixth gate drivers may be disposed on another side of the second peripheral area to be spaced apart from the side of the second peripheral area in the second direction with the display area interposed between the side and the another side of the second peripheral area.

In an embodiment, the plurality of bypass data lines may be disposed on the plurality of bypass gate lines.

In an embodiment, the plurality of bypass data lines may be disposed on a same layer.

In an embodiment, the display device may further include a driving voltage line disposed between the plurality of bypass data lines and the plurality of bypass gate lines in a cross-sectional view. The driving voltage line may overlap the plurality of bypass gate lines in a plan view.

An electronic device according to an embodiment of the disclosure may include a display device and a processor configured to drive the display device, and wherein the display device includes a plurality of data lines disposed in a display area and extending in a first direction, a plurality of gate lines disposed in the display area and extending in a second direction intersecting the first direction, a plurality of bypass data lines electrically connected to the plurality of data lines and disposed in a first peripheral area adjacent to the display area, and a plurality of bypass gate lines electrically connected to the plurality of gate lines, disposed in the first peripheral area, and alternately disposed in at least two layers.

In the display devices according to embodiments of the disclosure, a planar area of the plurality of bypass gate lines that spaced apart from each other may be reduced by alternately disposing the plurality of bypass gate lines on two layers. Simply put, by arranging the bypass gate lines on different layers in a cross-sectional view spaced apart to prevent coupling, a size of the display area where the pixel emits light may be secured to be wider.

Accordingly, the planar size of the surrounding area surrounding the hole area in the display device may be reduced, and the user may efficiently use a wider screen when using the display device.

### BRIEF DESCRIPTION OF THE DRAWINGS

The accompanying drawings, which are included to provide a further understanding of the disclosure and are incorporated in and constitute a part of this specification, illustrate embodiments of the disclosure together with the description.

FIG. 1 is a perspective view for explaining a display device according to an embodiment of the disclosure.

FIG. 2 is a schematic block diagram for explaining the display device of FIG. 1.

FIG. 3 is an enlarged view for explaining pixels and gate lines disposed in area A of FIG. 2.

FIG. 4 is an enlarged view for explaining pixels and data lines disposed in area A of FIG. 2.

FIG. 5 is a plan view for explaining pixels, gate lines, and data lines disposed in area A of FIG. 2.

FIG. 6 is a schematic diagram of an equivalent circuit for explaining one of the pixels included in the display device of FIG. 2.

FIG. 7 is a schematic cross-sectional view taken along line I-I′ of FIG. 2.

FIG. 8 is a plan view for explaining bypass gate lines and bypass data lines disposed in the hole area and the first peripheral area of FIG. 1.

FIG. 9 is a schematic cross-sectional view taken along line II-II′ of FIG. 8.

FIG. 10 is a perspective view for explaining a display device according to another embodiment of the disclosure.

FIG. 11 is a schematic block diagram for explaining the display device of FIG. 10.

FIG. 12 is an enlarged view for explaining pixels and gate lines disposed in area B of FIG. 11.

FIG. 13 is an enlarged view for explaining pixels and data lines disposed in area B of FIG. 11.

FIG. 14 is a plan view for explaining pixels, gate lines, and data lines disposed in area B of FIG. 11.

FIG. 15 is a schematic diagram of an equivalent circuit for explaining one of the pixels included in the display device of FIG. 11.

FIG. 16 is a plan view for explaining bypass gate lines and bypass data lines disposed in the hole area and the first peripheral area of FIG. 10.

FIG. 17 is a schematic cross-sectional view taken along line III-III′ of FIG. 16.

FIG. 18 is block-diagram for showing an electronic device according to an embodiment of the disclosure.

FIG. 19 is schematic views for showing the electronic device according to various embodiments of FIG. 18.

### DETAILED DESCRIPTION OF THE EMBODIMENTS

Illustrative, non-limiting embodiments will be more clearly understood from the following detailed description in conjunction with the accompanying drawings.

In this specification, a plane may be defined by a first direction D1 and a second direction D2 that intersects the first direction D1. For example, the second direction D2 may be perpendicular to the first direction D1. In addition, a third direction D3 may be a normal direction of the plane. For example, the third direction D3 may be perpendicular to the plane formed by the first direction D1 and the second direction D2.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

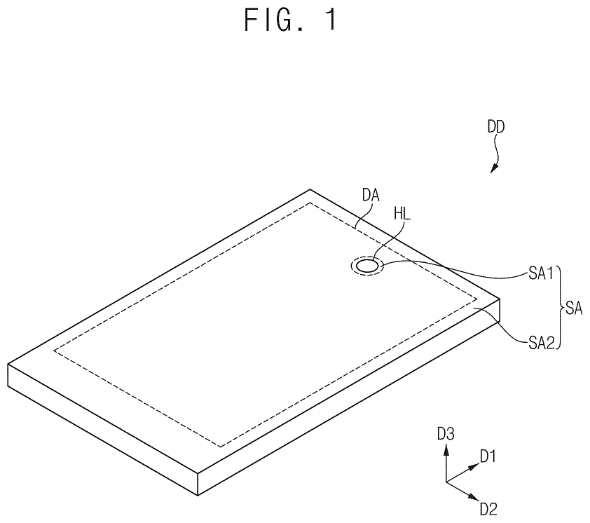

FIG. 1 is a perspective view for explaining a display device according to an embodiment of the disclosure.

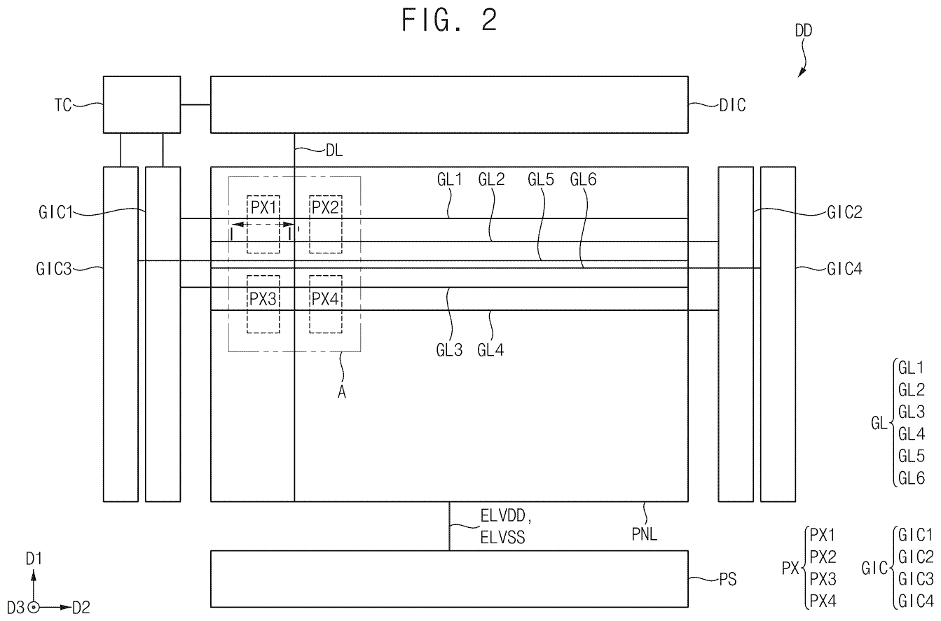

Referring to FIG. 1, a display device DD may include a display area DA that emits light and a peripheral area SA that does not emit light. The peripheral area SA may include a first peripheral area SA1 surrounded by the display area DA and a second peripheral area SA2 surrounding the display area DA in a plan view. The display device DD may provide an image using light emitted from multiple pixels (e.g., the pixels PX in FIG. 2) disposed in the display area DA.

The display device DD may include a hole area HL. The hole area HL may be at least partially surrounded by the display area DA. For example, as shown in FIG. 1, the hole area HL may be entirely surrounded by the display area DA. The first peripheral area SA1 may surround the hole area HL. For example, the first peripheral area SA1 may entirely surround the hole area HL, the display area DA may entirely surround the first peripheral area SA1, and the second peripheral area SA2 may entirely surround the display area DA. Accordingly, the first peripheral area SA1 may be disposed between the display area DA and the hole area HL. However, embodiments of the disclosure are not limited thereto.

The hole area HL may be a transmission area through which light or/and sound may be output from the display device DD to an outside or through which light or/and sound may be transmitted from the outside. In FIG. 1, the hole area HL is shown as having a circular shape, but embodiments of the disclosure are not limited thereto. A shape of the hole area HL may be circular, elliptical, or polygonal.

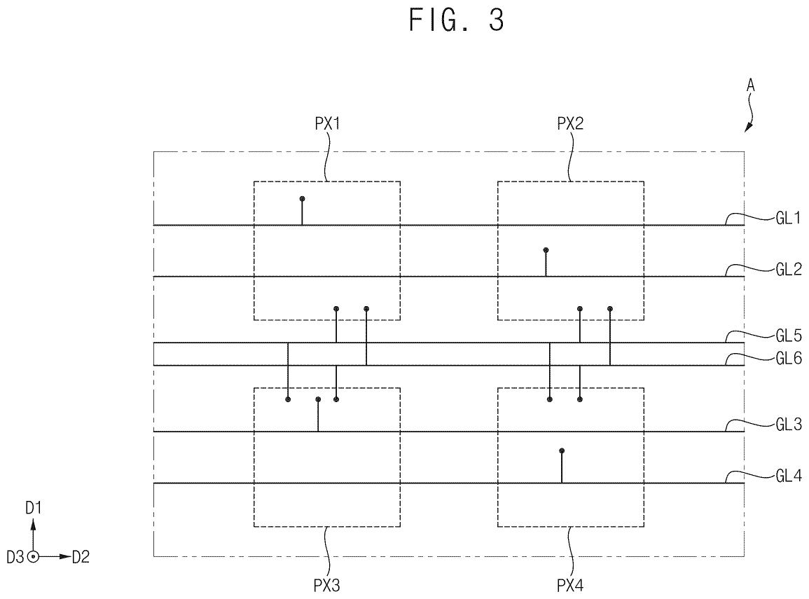

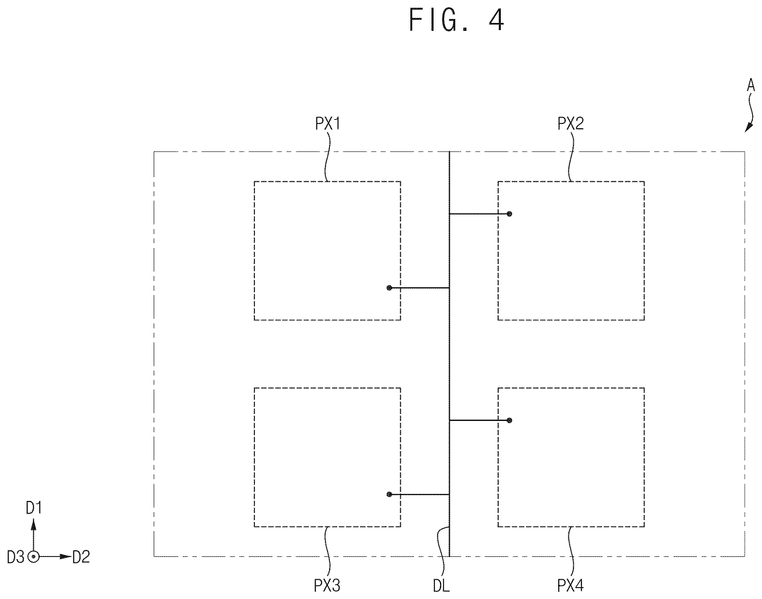

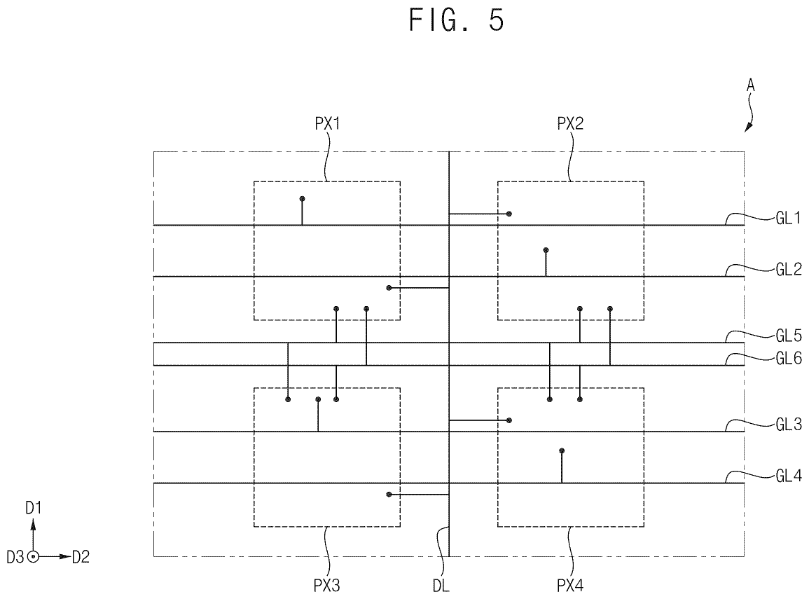

FIG. 2 is a schematic block diagram for explaining the display device of FIG. 1. FIG. 3 is an enlarged view for explaining pixels and gate lines disposed in area A of FIG. 2. FIG. 4 is an enlarged view for explaining pixels and data lines disposed in area A of FIG. 2. FIG. 5 is a plan view for explaining pixels, gate lines, and data lines disposed in area A of FIG. 2. For example, FIG. 5 is a plan view showing FIGS. 3 and 4 overlapping.

Referring to FIGS. 2 to 5, the display device DD may include a display panel PNL, a data driver DIC, data lines DL, a gate driver GIC, gate lines GL, a control portion TC, and a power driver PS.

The display panel PNL may be disposed in the display area (e.g., the display area DA in FIG. 1). The data driver DIC, the data lines DL, the gate driver GIC, the gate lines GL, the control portion TC, and the power driver PS may be disposed in the second peripheral area (e.g., the second peripheral area SA2 of FIG. 1).

Multiple pixels PX may be disposed on the display panel PNL. The pixels PX may include a first pixel PX1, a second pixel PX2, a third pixel PX3, and a fourth pixel PX4. The pixels PX may be repeatedly disposed in a matrix form in the first direction D1 and/or the second direction D2 in a plan view.

For example, the first pixel PX1 and the second pixel PX2 may be adjacent to each other in the second direction D2. For example, the second pixel PX2 may be spaced apart from the first pixel PX1 in the second direction D2. Likewise, the third pixel PX3 may be spaced apart from the first pixel PX1 in a direction opposite to the first direction D1. The fourth pixel PX4 may be spaced apart from the third pixel PX3 in the second direction D2. However, embodiments of the disclosure are not limited thereto.

Each of the first pixel PX1, the second pixel PX2, the third pixel PX3, and the fourth pixel PX4 may emit red, green, and/or blue light. However, embodiments of the disclosure are not limited thereto. Each of the first pixel PX1, the second pixel PX2, the third pixel PX3, and the fourth pixel PX4 may emit a combination of colors of red, green, and/or blue light.

The data driver DIC may be spaced apart from the display panel PNL in the first direction D1. The data driver DIC may supply a data signal to the data lines DL in response to a data control signal provided from the control portion TC. The data lines DL may extend in the first direction D1. The data lines DL may be spaced apart from each other in the second direction D2 and may transmit data signals to the pixels PX.

One of the data lines DL may transmit a data signal to the first pixel PX1 and the second pixel PX2. In an embodiment, one of the data lines DL may transmit a data signal to pixels PX disposed in two columns. For example, as shown in FIG. 2, one of the data lines DL may simultaneously transmit a data signal to the first pixel PX1 and the second pixel PX2.

The gate driver GIC may be disposed on sides of the display panel PNL. For example, the gate driver GIC may be disposed on sides of the display panel PNL in the second direction D2. The gate driver GIC may supply a gate signal to the gate lines GL in response to a gate control signal provided from the control portion TC. The gate lines GL may extend in the second direction D2. The gate lines GL may be spaced apart from each other in the first direction D1 and may transmit a gate signal to the pixels PX.

The gate driver GIC may include a first gate driver GIC1, a second gate driver GIC2, a third gate driver GIC3, and a fourth gate driver GIC4. For example, the first gate driver GIC1 and the third gate driver GIC3 may be spaced apart from the display panel PNL in a direction opposite to the second direction D2. For example, the second gate driver GIC2 and the fourth gate driver GIC4 may be spaced apart from the display panel PNL in the second direction D2. For example, the second gate driver GIC2 and the fourth gate driver GIC4 may be disposed on a side of the second peripheral area SA2 to be spaced apart in the second direction D2 with the first gate driver GIC1 and the third gate driver GIC3 and the display area DA interposed therebetween. However, embodiments of the disclosure are not limited thereto.

The gate lines GL may include a first gate line GL1, a second gate line GL2, a third gate line GL3, a fourth gate line GL4, a fifth gate line GL5, and a sixth gate line GL6. The first, second, third, fourth, fifth, and sixth gate lines GL1, GL2, GL3, GL4, GL5, and GL6 may be disposed on the display panel PNL extending in the second direction D2. The gate lines GL may be spaced apart from each other in the first direction D1. The gate lines GL may transmit gate signals to the pixels PX.

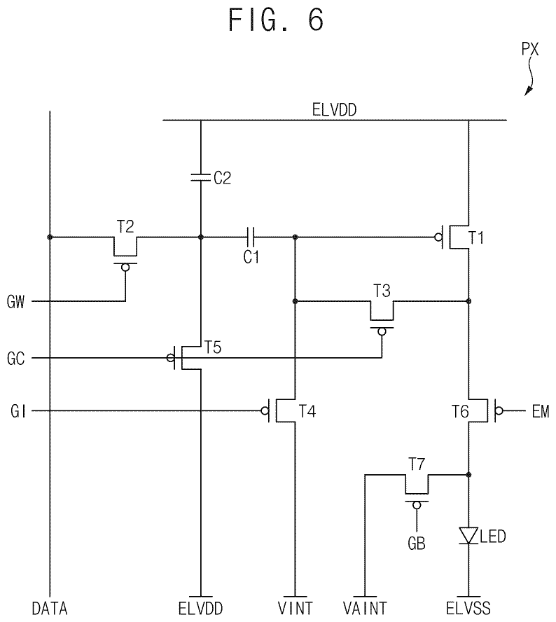

The first gate line GL1 may be electrically connected to the first gate driver GIC1 and the first pixel PX1. For example, the first gate line GL1 may receive a first gate signal from the first gate driver GIC1 and transmit the first gate signal to the first pixel PX1. The first gate signal may be a gate writing signal (e.g., the gate writing signal GW of FIG. 6).

The second gate line GL2 may be electrically connected to the second gate driver GIC2 and the second pixel PX2. For example, the second gate line GL2 may receive a second gate signal from the second gate driver GIC2 and transmit the second gate signal to the second pixel PX2. The second gate signal may be a gate writing signal (e.g., the gate writing signal GW of FIG. 6).

The third gate line GL3 may be electrically connected to the first gate driver GIC1 and the third pixel PX3. For example, the third gate line GL3 may receive a third gate signal from the first gate driver GIC1 and transmit the third gate signal to the third pixel PX3. The third gate signal may be a gate writing signal (e.g., the gate writing signal GW of FIG. 6).

The fourth gate line GL4 may be electrically connected to the second gate driver GIC2 and the fourth pixel PX4. For example, the fourth gate line GL4 may receive a fourth gate signal from the second gate driver GIC2 and transmit the fourth gate signal to the fourth pixel PX4. The fourth gate signal may be a gate writing signal (e.g., the gate writing signal GW of FIG. 6).

The fifth gate line GL5 may be electrically connected to the third gate driver GIC3 and the first, second, third, and fourth pixels PX1, PX2, PX3, and PX4. For example, the fifth gate line GL5 may receive a fifth gate signal from the third gate driver GIC3 and transmit the fifth gate signal to the first, second, third, and fourth pixels PX1, PX2, PX3, and PX4. The fifth gate signal may be a gate initialization signal GI (e.g., the gate initialization GI in FIG. 6), a gate compensation signal (e.g., the gate writing signal GC in FIG. 6), or a gate bias signal. (e.g., the gate bias signal GB in FIG. 6).

The sixth gate line GL6 may be electrically connected to the fourth gate driver GIC4 and the first, second, third, and fourth pixels PX1, PX2, PX3, and PX4. For example, the sixth gate line GL6 may receive a sixth gate signal from the fourth gate driver GIC4 and transmit the sixth gate signal to the first, second, third, and fourth pixels PX1, PX2, PX3, and PX4. The sixth gate signal may be an emission control signal (e.g., the emission control signal EM of FIG. 6).

FIG. 6 is a schematic diagram of an equivalent circuit for explaining one of the pixels included in the display device of FIG. 2.

Referring to FIGS. 2 and 6, each of the pixels PX of the display device DD may include first, second, third, fourth, fifth, sixth, and seventh transistors T1, T2, T3, T4, T5, T6, and T7, first and second capacitors C1, C2 and a light emitting diode LED.

The first transistor Tl may include a gate electrode, a first electrode, and a second electrode. The gate electrode of the first transistor TI may be connected to a first electrode of the first capacitor C1. The first electrode of the first transistor Tl may be connected to a first electrode of the third transistor T3. A driving voltage ELVDD may be applied to the second electrode of the first transistor T1.

The second transistor T2 may include a gate electrode, a first electrode, and a second electrode. The gate writing signal GW may be applied to the gate electrode of the second transistor T2. The first electrode of the second transistor T2 may be connected to a second electrode of the first capacitor C1. A data signal DATA may be applied to the second electrode of the second transistor T2.

The third transistor T3 may include a gate electrode, a first electrode, and a second electrode. The gate compensation signal GC may be applied to the gate electrode of the third transistor T3. The first electrode of the third transistor T3 may be connected to the first electrode of the first transistor T1. The second electrode of the third transistor T3 may be connected to the first electrode of the first capacitor C1.

The fourth transistor T4 may include a gate electrode, a first electrode, and a second electrode. A gate initialization signal GI may be applied to the gate electrode of the fourth transistor T4. A first initialization voltage VINT may be applied to the first electrode of the fourth transistor T4. The second electrode of the fourth transistor T4 may be connected to the second electrode of the third transistor T3.

The fifth transistor T5 may include a gate electrode, a first electrode, and a second electrode. The gate compensation signal GC may be applied to the gate electrode of the fifth transistor T5. The driving voltage ELVDD may be applied to the first electrode of the fifth transistor T5. The second electrode of the fifth transistor T5 may be connected to the second electrode of the first capacitor C1.

The sixth transistor T6 may include a gate electrode, a first electrode, and a second electrode. The emission control signal EM may be applied to the gate electrode of the sixth transistor T6. The first electrode of the sixth transistor T6 may be connected to a first electrode of the seventh transistor T7. The second electrode of the sixth transistor T6 may be connected to the first electrode of the third transistor T3.

The seventh transistor T7 may include a gate electrode, the first electrode, and a second electrode. The gate bias signal GB may be applied to the gate electrode of the seventh transistor T7. The first electrode of the seventh transistor T7 may be connected to the first electrode of the sixth transistor T6. A second initialization voltage VAINT may be applied to the second electrode of the seventh transistor T7.

The first capacitor C1 may include the first electrode and the second electrode. The first electrode of the first capacitor C1 may be connected to the gate electrode of the first transistor T1. The second electrode of the first capacitor C1 may be connected to the first electrode of the second transistor T2. The first capacitor Cl may be a storage capacitor.

The second capacitor C2 may include a first electrode and a second electrode. The first electrode of the second capacitor C2 may be connected to the second electrode of the first capacitor C1. The driving voltage ELVDD may be applied to the second electrode of the second capacitor C2. The second capacitor C2 may be a hold capacitor.

The light emitting diode LED may include a first electrode and a second electrode. The first electrode of the light emitting diode LED may be connected to the first electrode of the sixth transistor T6. A common voltage ELVSS may be applied to the second electrode of the light emitting diode LED.

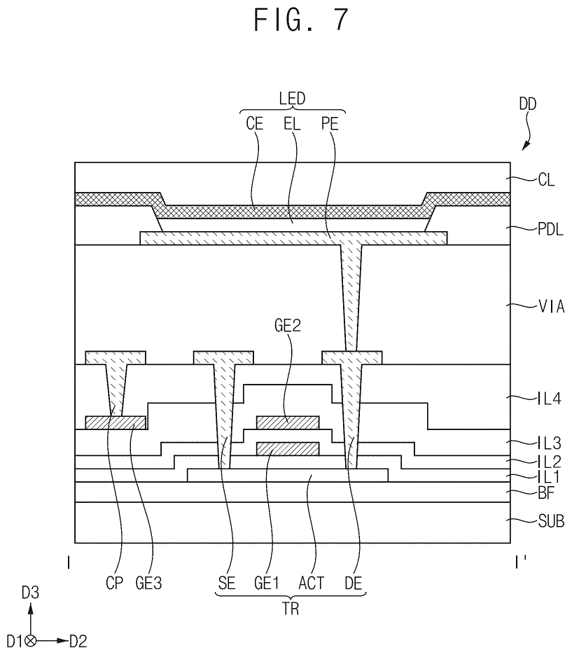

FIG. 7 is a schematic cross-sectional view taken along line I-I′ of FIG. 2.

Referring to FIGS. 2 and 7, the display device DD may include a substrate SUB, a buffer layer BF, first, second, third, and fourth insulating layers IL1, IL2, IL3, and IL4, a transistor TR, second and third gate electrodes GE2 and GE3, a conductive pattern CP, a via layer VIA, a light emitting diode LED, a pixel defining layer PDL, an encapsulation layer CL, etc. The transistor TR may include an active layer ACT, a first gate electrode GE1, a source electrode SE, and a drain electrode DE, and the light emitting diode LED may include a pixel electrode PE, a light emitting layer EL, and a common electrode CE.

The substrate SUB may be a glass substrate, a metal substrate, a plastic substrate, etc. However, embodiments of the disclosure are not limited thereto, and the substrate SUB may be an inorganic layer, an organic layer, or a composite material layer.

The buffer layer BF may be disposed on the substrate SUB. The buffer layer BF may prevent impurities such as oxygen and moisture from penetrating into an upper part of the substrate SUB. The buffer layer BF may include an inorganic insulating material.

The active layer ACT may be disposed on the buffer layer BF. The active layer ACT may include an oxide semiconductor, a silicon semiconductor, an organic semiconductor, etc. For example, the oxide semiconductor may include indium (In), gallium (Ga), tin (Sn), zirconium (Zr), vanadium (V), hafnium (Hf), cadmium (Cd), germanium (Ge), chromium (Cr), titanium (Ti), zinc (Zn), or a combination thereof. The silicon semiconductor may include amorphous silicon, polycrystalline silicon, etc. The active layer ACT may include a source region, a drain region, and a channel region disposed between the source region and the drain region.

The first insulating layer IL1 may be disposed on the buffer layer BF and the active layer ACT. For example, the first insulating layer IL1 may be disposed on the buffer layer BF and cover the active layer ACT. The first insulating layer IL1 may include a silicon compound, a metal oxide, etc. The silicon compounds that may be used in the first insulating layer IL1 may include silicon oxide (SiOₓ), silicon nitride (SiNₓ), silicon carbide (SiCₓ), silicon oxycarbide (SiOₓCy), silicon oxynitride (SiOₓN_{y}), and silicon carbonitride (SiCₓN_{y}). The metal oxide that may be used in the first insulating layer IL1 may include aluminum oxide (AlO), aluminum nitride (AlN), tantalum oxide (TaO), hafnium oxide (HfO), zirconium oxide (ZrO), and titanium oxide. (TiO). These may be used alone or in combination with each other. In another embodiment, the first insulating layer IL1 may have a multilayer structure including multiple insulating layers.

The first gate electrode GE1 may be disposed on the first insulating layer IL1. The first gate electrode GE1 may overlap the channel region of the active layer ACT in a plan view. The first gate electrode GE1 may include a metal, an alloy, a metal nitride, a conductive metal oxide, a transparent conductive material, etc. These may be used alone or in combination with each other. In another embodiment, the first gate electrode GE1 may have a multilayer structure including multiple metal layers.

The second insulating layer IL2 may be disposed on the first insulating layer IL1 and the first gate electrode GE1. For example, the second insulating layer IL2 may be disposed on the first insulating layer IL1 and cover the first gate electrode GE1. The second insulating layer IL2 may include a silicon compound, a metal oxide, etc. These may be used alone or in combination with each other. In another embodiment, the second insulating layer IL2 may have a multilayer structure including multiple insulating layers.

The second gate electrode GE2 may be disposed on the second insulating layer IL2. The second gate electrode GE2 may overlap the first gate electrode GE1 in a plan view. The second gate electrode GE2 may form a capacitor together with the first gate electrode GE1. The second gate electrode GE2 may include a metal, an alloy, a metal nitride, a conductive metal oxide, a transparent conductive material, etc. These may be used alone or in combination with each other. In another embodiment, the second gate electrode GE2 may have a multilayer structure including multiple metal layers.

The third insulating layer IL3 may be disposed on the second insulating layer IL2 and the second gate electrode GE2. For example, the third insulating layer IL3 may be disposed on the second insulating layer IL2 and cover the second gate electrode GE2. The third insulating layer IL3 may include a silicon compound, a metal oxide, etc. These may be used alone or in combination with each other. In another embodiment, the third insulating layer IL3 may have a multilayer structure including multiple insulating layers.

The third gate electrode GE3 may be disposed on the third insulating layer IL3. The third gate electrode GE3 may include a metal, an alloy, a metal nitride, a conductive metal oxide, a transparent conductive material, etc. These may be used alone or in combination with each other. In another embodiment, the third gate electrode GE3 may have a multilayer structure including multiple metal layers.

The fourth insulating layer IL4 may be disposed on the third insulating layer IL3 and the third gate electrode GE3. For example, the fourth insulating layer IL4 may be disposed on the third insulating layer IL3 and cover the third gate electrode GE3. The fourth insulating layer IL4 may include a silicon compound, a metal oxide, etc. These may be used alone or in combination with each other. In another embodiment, the fourth insulating layer IL4 may have a multilayer structure including multiple insulating layers.

The source electrode SE, the drain electrode DE, and the conductive pattern CP may be disposed on the fourth insulating layer IL4. The conductive pattern CP may be connected to the third gate electrode GE3 through a contact hole formed by removing a portion of the fourth insulating layer IL4. The source electrode SE may be connected to the source region of the active layer ACT through a contact hole formed by removing a portion of each of the first, second, third, and fourth insulating layers IL1, IL2, IL3, and IL4, and the drain electrode DE may be connected to the drain region of the active layer ACT through a contact hole formed by removing a portion of each of the first, second, third, and fourth insulating layers IL1, IL2, IL3, and IL4. Each of the conductive pattern CP, the source electrode SE, and the drain electrode DE may include a metal, an alloy, a metal nitride, a conductive metal oxide, a transparent conductive material, etc. These may be used alone or in combination with each other. In another embodiment, each of the conductive pattern CP, the source electrode SE, and the drain electrode DE may have a multilayer structure including multiple metal layers.

The via layer VIA may be disposed on the fourth insulating layer IL4, the conductive pattern CP, the source electrode SE, and the drain electrode DE. The via layer VIA may cover the conductive pattern CP, the source electrode SE, and the drain electrode DE. For example, the via layer VIA may include an organic material or an inorganic material. Organic materials that may be used in the via layer VIA may include a photoresist, a polyacryl-based resin, a polyimide-based resin, a polyamide-based resin, a siloxane-based resin, an acryl-based resin, an epoxy-based resin, etc. These may be used alone or in combination with each other.

The pixel electrode PE may be disposed on the via layer VIA. The pixel electrode PE may be connected to the drain electrode DE through a contact hole formed by removing a portion of the via layer VIA. The pixel electrode PE may be an anode electrode. The pixel electrode PE may include a metal, an alloy, a metal nitride, a conductive metal oxide, a transparent conductive material, etc. These may be used alone or in combination with each other. In another embodiment, the pixel electrode PE may have a multilayer structure including multiple metal layers.

The pixel defining layer PDL may be disposed on the via layer VIA and the pixel electrode PE. The pixel defining layer PDL may cover sides of the pixel electrode PE and expose at least a portion of a top surface of the pixel electrode PE. The pixel defining layer PDL may include an organic material or an inorganic material.

The light emitting layer EL may be disposed on the pixel electrode PE. The light emitting layer EL may emit red, green, or blue light. The light emitting layer EL may include a hole injection layer, a hole transport layer, an organic emission layer, an electron transport layer, and an electron injection layer.

A common electrode CE may be disposed on the light emitting layer EL. The common electrode CE may include a metal, an alloy, a metal nitride, a conductive metal oxide, a transparent conductive material, etc. These may be used alone or in combination with each other. In another embodiment, the common electrode CE may have a multilayer structure including multiple metal layers. The common electrode CE may be a cathode electrode.

Although the display device DD of the disclosure is described based on an organic light emitting display device (OLED) according to an embodiment, a configuration of the disclosure is not limited thereto. In other embodiments, the display device DD may be a liquid crystal display device (LCD), a field emission display device (FED), a plasma display device (PDP), or an electrophoretic image display device (EPD).

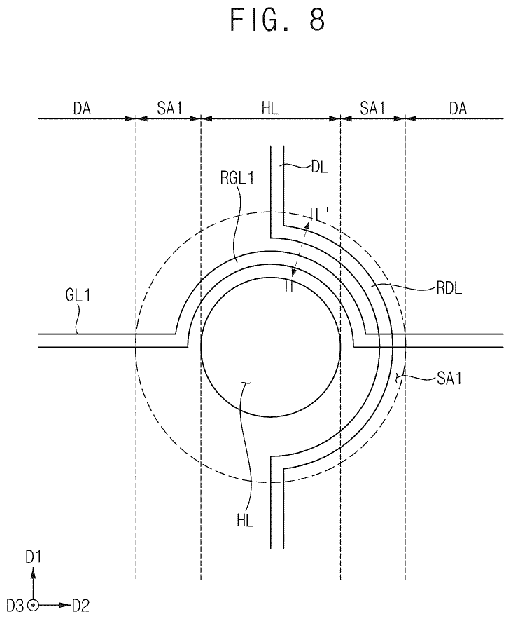

FIG. 8 is a plan view for explaining bypass gate lines and bypass data lines disposed in the hole area and the first peripheral area of FIG. 1.

Referring to FIGS. 1 and 8, a first bypass gate line RGL1 and bypass data lines RDL may be disposed adjacent to the hole area HL of the display device DD.

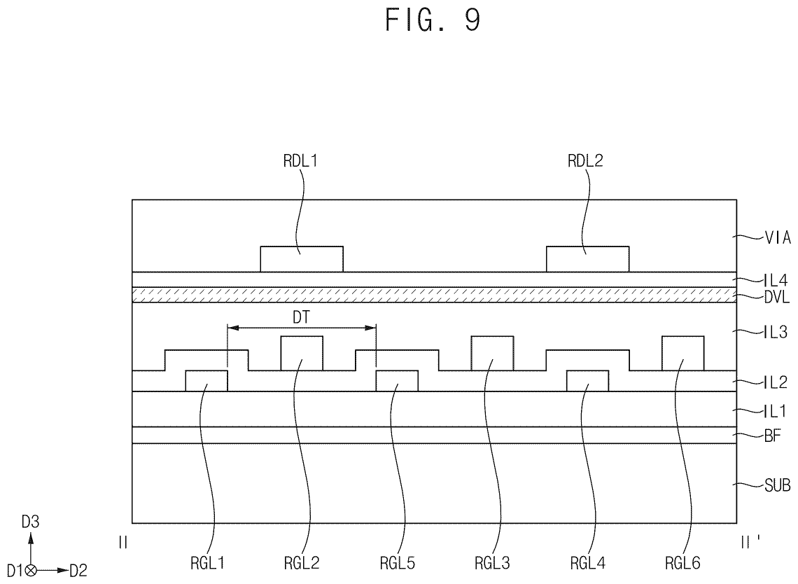

The first bypass gate line RGL1 may be disposed in the first peripheral area SA1. The first bypass gate line RGL1 may bypass the hole area HL along the first peripheral area SA1. For example, as shown in FIG. 8, the first bypass gate line RGL1 may be connected to the first gate line GL1 and may be disposed in the first peripheral area SA1 surrounding the hole area HL. In FIG. 8, only one bypass gate line RGL1 is disposed, but the embodiment of the disclosure is not limited thereto. The first peripheral area SA1 may further include at least another bypass gate line (see FIG. 9).

The bypass data lines RDL may be disposed in the first peripheral area SA1. The bypass data lines RDL may be disposed in the peripheral area SA1 to bypass along the hole area HL. For example, as shown in FIG. 8, bypass data lines RDL may be connected to one of the data lines DL, and may be disposed in the first peripheral area SA1 to bypass the hole area HL.

FIG. 9 is a schematic cross-sectional view taken along line II-II′ of FIG. 8. Since some of the configurations described in FIG. 9 may overlap with the configurations described in FIG. 7, overlapping contents may be omitted or simplified.

Referring to FIGS. 7 and 9, the substrate SUB, the buffer layer BF, the first, second, third, and fourth insulating layers IL1, IL2, IL3, and IL4, the via layer VIA, first, second, third, fourth, fifth, and sixth bypass gate lines RGL1, RGL2, RGL3, RGL4, RGL5, and RGL6, a driving voltage line DVL, and first and second bypass data lines RDL1 and RDL2 may be disposed in the hole area HL.

In an embodiment, the first, second, third, fourth, fifth, and sixth bypass gate lines RGL1, RGL2, RGL3, RGL4, RGL5, and RGL6 may be alternately disposed in different layers. For example, the first, second, third, fourth, fifth, and sixth bypass gate lines RGL1, RGL2, RGL3, RGL4, RGL5, and RGL6 may be alternately disposed in the second insulating layer IL2 and the third insulating layer IL3.

The first bypass gate line RGL1, the fourth bypass gate line RGLA, and the fifth bypass gate line RGL5 may be disposed on a same layer. The first bypass gate line RGL1, the fourth bypass gate line RGL4, and the fifth bypass gate line RGL5 may be disposed on the first insulating layer IL1. For example, the first bypass gate line RGL1, the fourth bypass gate line RGL4, and the fifth bypass gate line RGL5 may be disposed on the first insulating layer IL1 and may be covered by the second insulating layer IL2.

In an embodiment, the first bypass gate line RGL1 and the fifth bypass gate line RGL5 may be disposed with a separation distance DT in the second direction D2. For example, the separation distance DT may be in a range of about 2 μm to about 5 μm. For example, the separation distance DT may be in a range of about 2 μm to about 3.5 μm. The separation distance DT may be a distance between each of the bypass gate lines disposed on a same layer. By arranging the bypass gate lines with the separation distance DT, coupling between the bypass gate lines may be prevented.

The second bypass gate line RGL2, the third bypass gate line RGL3, and the sixth bypass gate line RGL6 may be disposed on a same layer. The second bypass gate line RGL2, the third bypass gate line RGL3, and the sixth bypass gate line RGL6 may be disposed on the second insulating layer IL2. For example, the second bypass gate line RGL2, the third bypass gate line RGL3, and the sixth bypass gate line RGL6 may be disposed on the second insulating layer IL2 and may be covered by the third insulating layer IL3.

The first bypass data line RDL1 and the second bypass data line RDL2 may be disposed on the fourth insulating layer IL4. For example, the first bypass data line RDL1 and the second bypass data line RDL2 may be disposed on a same layer. However, embodiments of the disclosure are not limited thereto.

As the first bypass gate line RGL1, the fourth bypass gate line RGL4, and the fifth bypass gate lines RGL5 are disposed on the first insulating layer IL1, and the second bypass gate line RGL2, the third bypass gate line RGL3, and the sixth bypass gate lines RGL6 are alternately disposed on the second insulating layer IL2, a size of the first peripheral area SA1 may be reduced. Simply put, as the first, second, third, fourth, fifth, and sixth bypass gate lines RGL1, RGL2, RGL3, RGL4, RGL5, and RGL6 are alternately disposed in different layers, a size of the area disposed in the second direction D2 may decrease.

However, embodiments of the disclosure are not limited thereto. The first, second, third, fourth, fifth, and sixth bypass gate lines RGL1, RGL2, RGL3, RGL4, RGL5, and RGL6 may be freely disposed alternately with each other on the first insulating layer IL1 and the second insulating layer IL2. The first, second, third, fourth, fifth, and sixth bypass gate lines RGL1, RGL2, RGL3, RGL4, RGL5, and RGL6 may be disposed on insulating layers other than the first insulating layer IL1 and the second insulating layer IL2.

The driving voltage line DVL may be disposed on the third insulating layer IL3. The driving voltage line DVL may transmit the driving voltage (e.g., the driving voltage ELVDD of FIG. 6). The driving voltage line DVL may transmit a driving voltage to the pixels (e.g., the pixels PX in FIG. 2).

In an embodiment, the driving voltage line DVL may overlap the first, second, third, fourth, fifth, and sixth bypass gate lines RGL1, RGL2, RGL3, RGL4, RGL5, and RGL6 in a plan view. As the driving voltage line DVL may be between the first, second, third, fourth, fifth, and sixth bypass gate lines RGL1, RGL2, RGL3, RGL4, RGL5, and RGL6 and the first and second bypass data lines RDL1 and RDL2 in a cross sectional view, a coupling effect between the first, second, third, fourth, fifth, and sixth bypass gate lines RGL1, RGL2, RGL3, RGLA, RGL5, and RGL6 and the first and second bypass data lines RDL1 and RDL2 may be prevented.

The first and second bypass data lines RDL1 and RDL2 may be disposed on the fourth insulating layer IL4. The first and second bypass data lines RDL1 and RDL2 may transmit data signals to the pixels (e.g., the pixels PX in FIG. 2). Each of the first bypass data line RDL1 and the second bypass data line RDL2 may apply data to pixels PX disposed in two columns, as shown in FIG. 2.

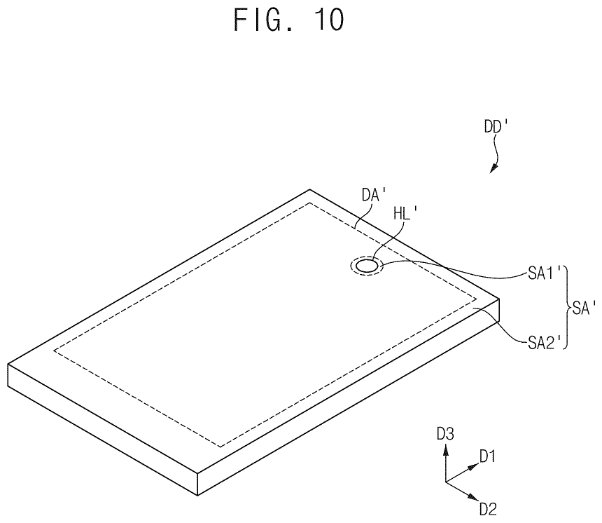

FIG. 10 is a perspective view for explaining a display device according to another embodiment of the disclosure. FIG. 10 may have substantially a same configuration as that described in FIG. 1. Therefore, overlapping content may be omitted or simplified.

Referring to FIG. 10, the display device DD′ may include a display area DA′ that emits light and a peripheral area SA′ that does not emit light. The peripheral area SA′ may include a first peripheral area SA1′ surrounded by the display area DA′ and a second peripheral area SA2′ surrounding the display area DA′.

The display device DD′ may include a hole area HL′. The hole area HL′ may be at least partially surrounded by the display area DA′. For example, as shown in FIG. 10, the hole area HL′ may be entirely surrounded by the display area DA′.

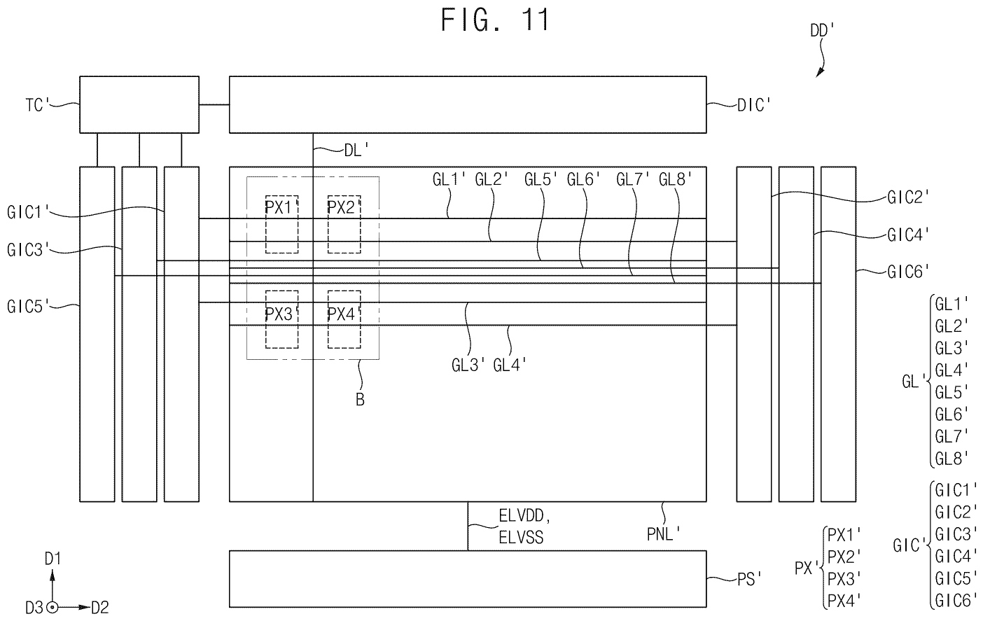

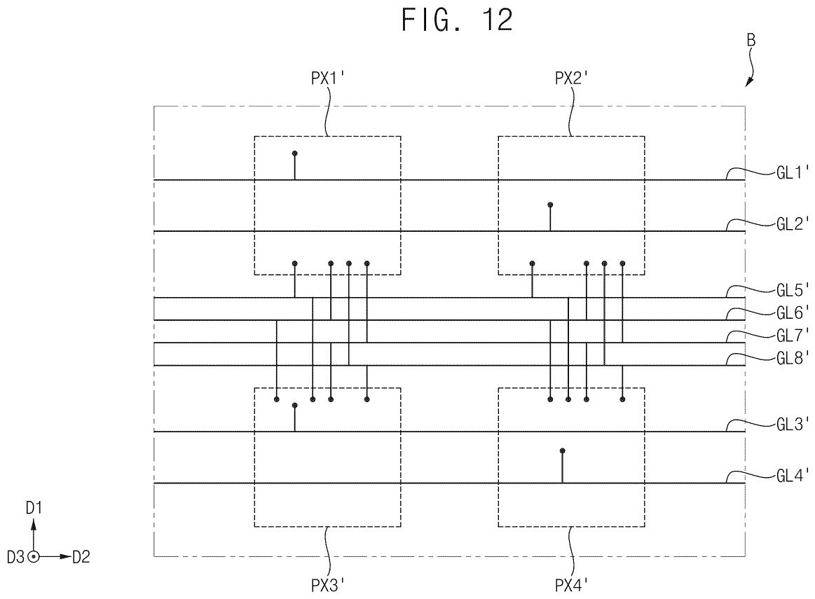

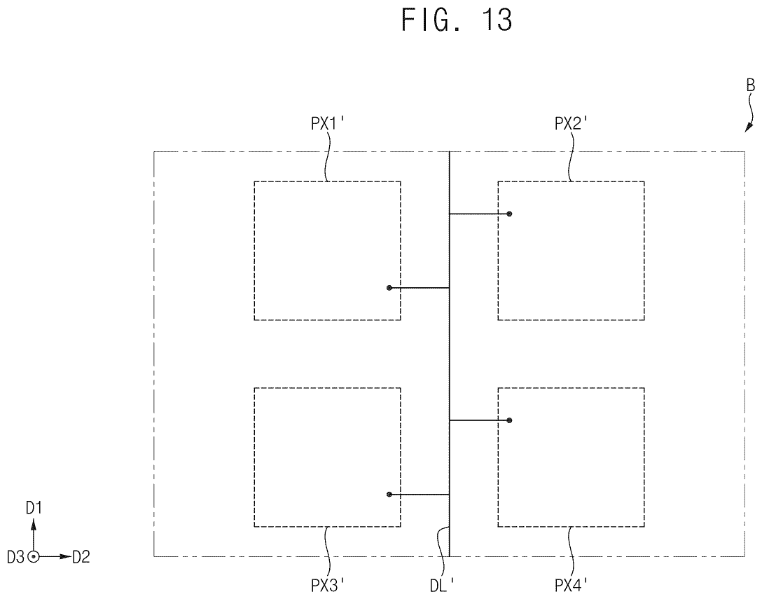

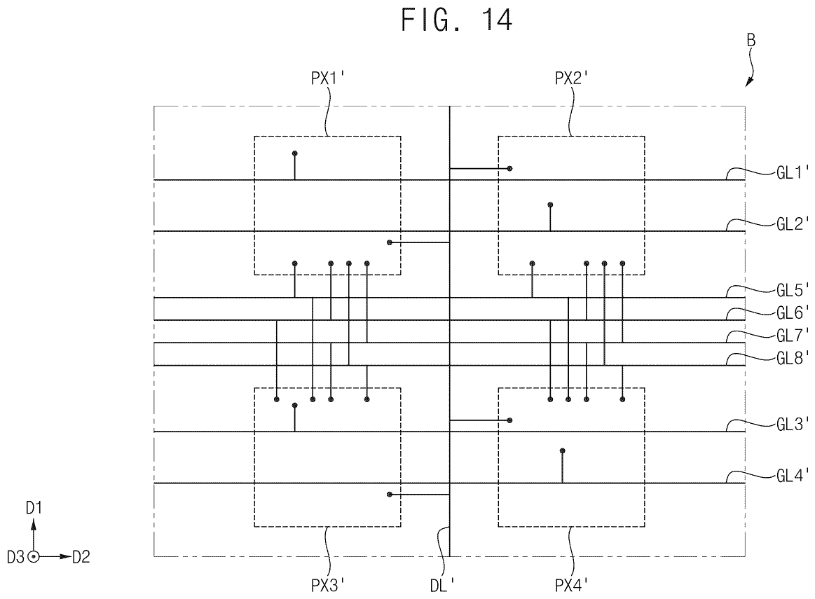

FIG. 11 is a schematic block diagram for explaining the display device of FIG. 10. FIG. 12 is an enlarged view for explaining pixels and gate lines disposed in area B of FIG. 11. FIG. 13 is an enlarged view for explaining pixels and data lines disposed in area B of FIG. 11. FIG. 14 is a plan view for explaining pixels, gate lines, and data lines disposed in area B of FIG. 11. For example, FIG. 14 is a plan view showing FIGS. 12 and 13 overlapping each other. FIGS. 11, 12, 13, and 14 may have substantially a same configuration as the configuration described in FIGS. 2, 3, 4, and 5. Therefore, overlapping content may be omitted or simplified.

Referring to FIGS. 11, 12, 13, and 14, the display device DD′ may include a display panel PNL′, a data driver DIC′, data lines DL′, a gate driver GIC′, a gate line GL′, a control portion TC′, and a power driver PS′.

Multiple pixels PX′ may be disposed on the display panel PNL′. The pixels PX′ may include a first pixel PX1′, a second pixel PX2′, a third pixel PX3′, and a fourth pixel PX4′. The pixels PX′ may be repeatedly disposed in a matrix form in the first direction D1 and/or the second direction D2 in a plan view.

The data driver DIC′ may be spaced apart from the display panel PNL′ in the first direction D1. The data driver DIC′ may supply a data signal to the data lines DL′ in response to a data control signal provided from the control portion TC′. The data lines DL′ may extend in the first direction D1. The data lines DL′ may be spaced apart from each other in the second direction D2 and may transmit data signals to the pixels PX′.

The gate driver GIC′ may be disposed on sides of the display panel PNL′. For example, the gate driver GIC′ may be disposed on sides of the display panel PNL′ in the second direction D2. The gate driver GIC′ may supply a gate signal to the gate lines GL′ in response to a gate control signal provided from the control portion TC′. The gate lines GL′ may extend in the second direction D2. The gate lines GL′ may be spaced apart from each other in the first direction D1 and may transmit a gate signal to the pixels PX′.

The gate driver GIC′ may include a first gate driver GIC1′, a second gate driver GIC2′, a third gate driver GIC3′, a fourth gate driver GIC4′, a fifth gate driver GIC5′, and a sixth gate driver GIC6′. For example, the first gate driver GIC1′, the third gate driver GIC3′, and the fifth gate driver GIC5′ may be spaced apart from the display panel PNL′ in a direction opposite to the second direction D2. On the contrary, the second gate driver GIC2′, the fourth gate driver GIC4′, and the sixth gate driver GIC6′ may be spaced apart from the display panel PNL′ in the second direction D2. For example, the second gate driver GIC2′, the fourth gate driver GIC4′, and the sixth gate driver GIC6′ may be disposed on a side of the second peripheral area SA2′ to be spaced apart in the second direction D2 with the first gate driver GIC1′, the third gate driver GIC3′, the fifth gate driver GIC5′, and the display area DA′ interposed therebetween. However, embodiments of the disclosure are not limited thereto.

The gate lines GL′ may include a first gate line GL1′, a second gate line GL2′, a third gate line GL3′, a fourth gate line GL4′, a fifth gate line GL5′, a sixth gate line GL6′, a seventh gate line GL7′, and an eighth gate line GL8′. The gate lines GL′ may be disposed on the display panel PNL′ extending in the second direction D2. The gate lines GL′ may be spaced apart from each other in the first direction D1. The gate lines GL′ may transmit gate signals to the pixels PX′.

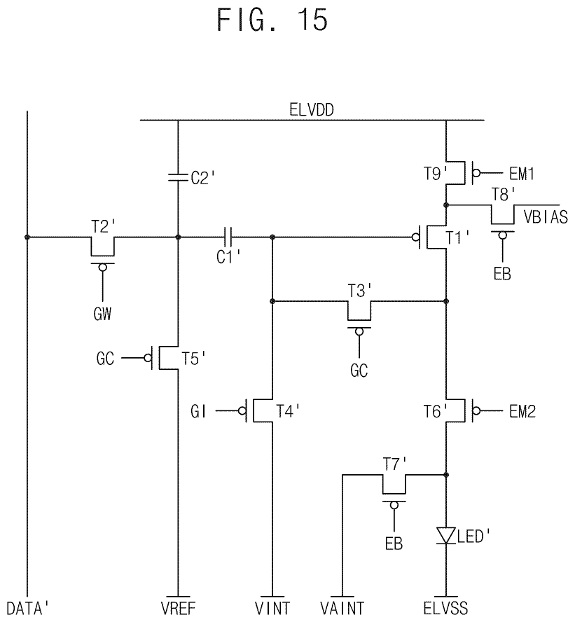

The first gate line GL1′ may be electrically connected to the first gate driver GIC1′ and the first pixel PX1′. For example, the first gate line GL1′ may receive a first gate signal from the first gate driver GIC1′ and transmit it to the first pixel PX1′. The first gate signal may be a gate writing signal (e.g., the gate writing signal GW of FIG. 15).

The second gate line GL2′ may be electrically connected to the second gate driver GIC2′ and the second pixel PX2′. For example, the second gate line GL2′ may receive a second gate signal from the second gate driver GIC2′ and transmit it to the second pixel PX2′. The second gate signal may be a gate writing signal (e.g., the gate writing signal GW of FIG. 15).

The third gate line GL3′ may be electrically connected to the first gate driver GIC1′ and the third pixel PX3′. For example, the third gate line GL3′ may receive a third gate signal from the first gate driver GIC1′ and transmit it to the third pixel PX3′. The third gate signal may be a gate writing signal (e.g., the gate writing signal GW of FIG. 15).

The fourth gate line GL4′ may be electrically connected to the second gate driver GIC2′ and the fourth pixel PX4′. For example, the fourth gate line GL4′ may receive a fourth gate signal from the second gate driver GIC2′ and transmit it to the fourth pixel PX4′. The fourth gate signal may be a gate writing signal (e.g., the gate writing signal GW of FIG. 15).

The fifth gate line GL5′ may be electrically connected to the third gate driver GIC3′ and the first, second, third, and fourth pixels PX1′, PX2′, PX3′, and PX4′. For example, the fifth gate line GL5′ may receive a fifth gate signal from the third gate driver GIC3′ and transmit it to the first, second, third, and fourth pixels PX1′, PX2′, PX3′, and PX4′. The fifth gate signal may be a gate initialization signal or a gate compensation signal (e.g., the gate initialization signal GI or gate compensation signal GC in FIG. 15).

The sixth gate line GL6′ may be electrically connected to the fourth gate driver GIC4′ and the first, second, third, and fourth pixels PX1′, PX2′, PX3′, and PX4′. For example, the sixth gate line GL6′ may receive a sixth gate signal from the fourth gate driver GIC4′ and transmit it to the first, second, third, and fourth pixels PX1′, PX2′, PX3′, and PX4′. The third gate signal may be the gate bias signal (e.g., the gate bias signal GB of FIG. 15).

The seventh gate line GL7′ may be electrically connected to the fourth gate driver GIC4 and the first, second, third, and fourth pixels PX1′, PX2′, PX3′, and PX4′. For example, the seventh gate line GL6′ may receive a seventh gate signal from the fourth gate driver GIC4′ and transmit it to the first, second, third, and fourth pixels PX1′, PX2′, PX3′, and PX4′. The seventh gate signal may be a first emission control signal (e.g., the first emission control signal EM1 in FIG. 15).

The eighth gate line GL8′ may be electrically connected to the fourth gate driver GIC4′ and the first, second, third, and fourth pixels PX1′, PX2′, PX3′, and PX4′. For example, the eighth gate line GL6′ may receive an eighth gate signal from the fourth gate driver GIC4′ and transmit it to the first, second, third, and fourth pixels PX1′, PX2′, PX3′, and PX4′. The eighth gate signal may be a second emission control signal (e.g., the second emission control signal EM2 in FIG. 15).

FIG. 15 is a schematic diagram of an equivalent circuit for explaining one of the pixels included in the display device of FIG. 11.

Referring to FIGS. 11 and 15, each of the pixels PX′ of the display device DD′ may include first, second, third, fourth, fifth, sixth, seventh, eighth, and ninth transistors T1′, T2′, T3′, T4′, T5′, T6′, T7′, T8′, and T9′, first and second capacitors C1′ and C2′, and a light emitting diode LED′.

The first transistor T1′ may include a gate electrode, a first electrode, and a second electrode. The gate electrode of the first transistor T1′ may be connected to a first electrode of the first capacitor C1′. The first electrode of the first transistor T1′ may be connected to the first electrode of the third transistor T3′. The second electrode of the first transistor T1′ may be connected to the second electrode of the eighth transistor T8′.

The second transistor T2′ may include a gate electrode, a first electrode, and a second electrode. A gate writing signal GW′ may be applied to the gate electrode of the second transistor T2′. The first electrode of the second transistor T2′ may be connected to a second electrode of the first capacitor C1′. A data signal DATA′ may be applied to the second electrode of the second transistor T2′.

The third transistor T3′ may include a gate electrode, the first electrode, and the second electrode. A gate compensation signal GC may be applied to the gate electrode of the third transistor T3′. The first electrode of the third transistor T3′ may be connected to the first electrode of the first transistor T1′. The second electrode of the third transistor T3′ may be connected to the first electrode of the first capacitor C1′.

The fourth transistor T4′ may include a gate electrode, a first electrode, and a second electrode. A gate initialization signal GI may be applied to the gate electrode of the fourth transistor T4′. The first initialization voltage VINT may be applied to the first electrode of the fourth transistor T4′. The second electrode of the fourth transistor T4′ may be connected to the second electrode of the third transistor T3′.

The fifth transistor T5′ may include a gate electrode, a first electrode, and a second electrode. A gate compensation signal GC may be applied to the gate electrode of the fifth transistor T5′. A reference voltage VREF may be applied to the first electrode of the fifth transistor T5′. The second electrode of the fifth transistor T5′ may be connected to the second electrode of the first capacitor C1′.

The sixth transistor T6′ may include a gate electrode, a first electrode, and a second electrode. A second emission control signal EM2 may be applied to the gate electrode of the sixth transistor T6′. The first electrode of the sixth transistor T6′ may be connected to the first electrode of the seventh transistor T7′. The second electrode of the sixth transistor T6′ may be connected to the first electrode of the third transistor T3′.

The seventh transistor T7′ may include a gate electrode, the first electrode, and the second electrode. The gate bias signal GB may be applied to the gate electrode of the seventh transistor T7′. The first electrode of the seventh transistor T7′ may be connected to the first electrode of the sixth transistor T6′. A second initialization voltage VAINT may be applied to the second electrode of the seventh transistor T7′.

The eighth transistor T8′ may include a gate electrode, a first electrode, and the second electrode. A bias control signal EB may be applied to the gate electrode of the eighth transistor T8′. The bias voltage VBIAS may be applied to the first electrode of the eighth transistor T8′. The second electrode of the eighth transistor T8′ may be connected to the second electrode of the first transistor T1′.

The ninth transistor T9′ may include a gate electrode, a first electrode, and a second electrode. The first emission control signal EM1 may be applied to the gate electrode of the ninth transistor T9′. The first electrode of the ninth transistor T9′ may be connected to the second electrode of the ninth transistor T9′. A driving voltage ELVDD may be applied to the second electrode of the ninth transistor T9′.

The first capacitor C1′ may include the first electrode and the second electrode. The first electrode of the first capacitor C1′ may be connected to the gate electrode of the first transistor T1′. The second electrode of the first capacitor C1′ may be connected to the first electrode of the second transistor T2′. The first capacitor C1′ may be a storage capacitor.

The second capacitor C2′ may include a first electrode and a second electrode. The first electrode of the second capacitor C2′ may be connected to the second electrode of the first capacitor C1′. The driving voltage ELVDD may be applied to the second electrode of the second capacitor C2′. The second capacitor C2′ may be a hold capacitor.

The light emitting diode LED′ may include a first electrode and a second electrode. The first electrode of the light emitting diode LED′ may be connected to the first electrode of the sixth transistor T6′. A common voltage ELVSS may be applied to the second electrode of the light emitting diode LED′.

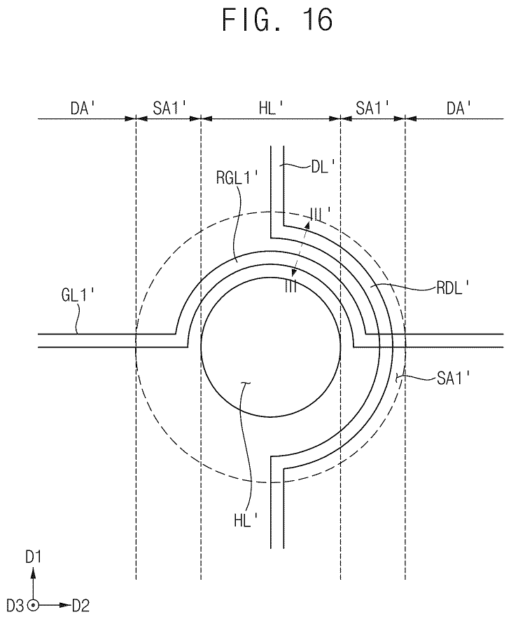

FIG. 16 is a plan view for explaining bypass gate lines and bypass data lines disposed in the hole area and the first peripheral area of FIG. 10. Since the configuration described in FIG. 16 is substantially a same as the configuration described in FIG. 8, overlapping content may be omitted or simplified.

Referring to FIGS. 10 and 16, bypass gate lines RGL′ and bypass data lines RDL′ may be disposed adjacent to the hole area HL′ of the display device DD′.

The bypass gate lines RGL′ may be disposed in the first peripheral area SA1′. For example, the first bypass gate lines RGL1′ may bypass the hole area HL′ along the first peripheral area SA1′.

The bypass data lines RDL′ may be disposed in the first peripheral area SA1′. The bypass data lines RDL′ may bypass the hole area HL′ along the first peripheral area SA1′.

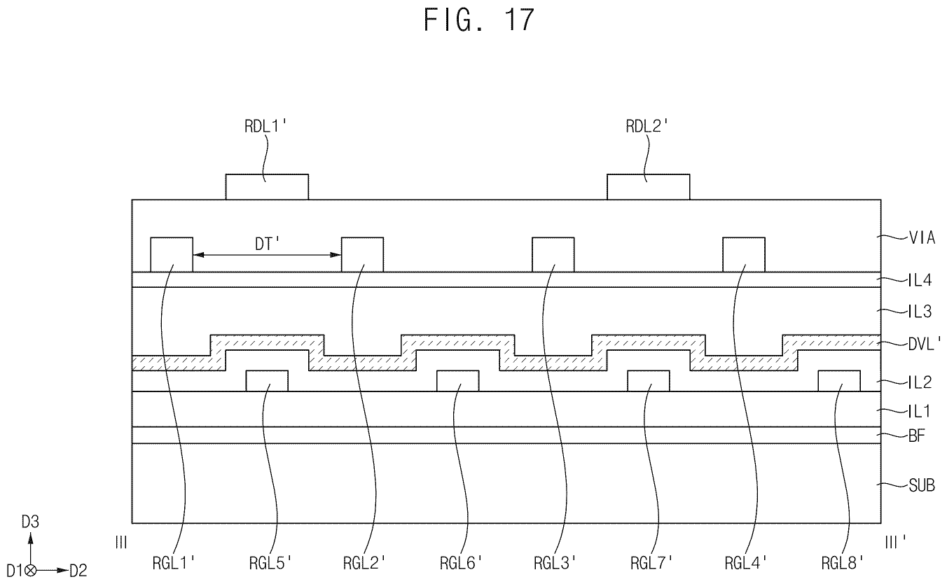

FIG. 17 is a schematic cross-sectional view taken along line III-III′ of FIG. 16. Since some of the configurations described in FIG. 17 may overlap with the configurations described in FIG. 9, overlapping contents may be omitted or simplified.

Referring to FIGS. 16 and 17, the substrate SUB, the buffer layer BF, the first, second, third, and fourth insulating layers IL1, IL2, IL3, and IL4, the via layer VIA, first, second, third, fourth, fifth, sixth, seventh, and eighth bypass gate lines RGL1′, RGL2′, RGL3′, RGLA′, RGL5′, RGL6′, RGL7′, and RGL8′, driving voltage line DVL′, and first and second bypass data lines RDL1′ and RDL2′ may be disposed in the hole area HL′.

In an embodiment, the first, second, third, fourth, fifth, sixth, seventh, and eighth bypass gate lines RGL1′, RGL2′, RGL3′, RGL4′, RGL5′, RGL6′, RGL7′, and RGL8′ may be alternately disposed in different layers. For example, the first, second, third, fourth, fifth, sixth, seventh, and eighth bypass gate lines RGL1′, RGL2′, RGL3′, RGL4′, RGL5′, RGL6′, RGL7′, and RGL8′ may be alternately disposed on the first insulating layer IL1 and the fourth insulating layer IL4.

The first, second, third, and fourth bypass gate lines RGL1′, RGL2′, RGL3′, and RGL4′ may be disposed on a same layer. The first, second, third, and fourth bypass gate lines RGL1′, RGL2′, RGL3′, and RGL4′ may be disposed on the fourth insulating layer IL4. For example, the first, second, third, and fourth bypass gate lines RGL1′, RGL2′, RGL3′, and RGLA′ may be disposed on the fourth insulating layer IL4 and covered by the via layer VIA.

In an embodiment, the first bypass gate line RGL1′ and the second bypass gate line RGL2′ may be disposed with a separation distance DT′ in the second direction D2. For example, the separation distance DT′ may be in a range of about 2 μm to about 5 μm. For example, the separation distance DT′ may be in a range of about 2 μm to about 3.5 μm.

The fifth, sixth, seventh, and eighth bypass gate lines RGL5′, RGL6′, RGL7′, and RGL8′ may be disposed on a same layer. The fifth, sixth, seventh, and eighth bypass gate lines RGL5′, RGL6′, RGL7′, and RGL8′ may be disposed on the first insulating layer IL1. For example, the fifth, sixth, seventh, and eighth bypass gate lines RGL5′, RGL6′, RGL7′, and RGL8′ may be disposed on the first insulating layer IL1 and covered by the second insulating layer IL2.

The first, second, third, and fourth bypass gate lines RGL1′, RGL2′, RGL3′, and RGL4′ may be disposed on the fourth insulating layer IL4, and the fifth, sixth, seventh, and eighth bypass gate lines RGL5′, RGL6′, RGL7′, and RGL8′ may be disposed on the first insulating layer IL1, thereby reducing a size of the first peripheral area SA1. Simply put, the first, second, third, fourth, fifth, sixth, seventh, and eighth bypass gate lines RGL1′, RGL2′, RGL3′, RGL4′, RGL5′, RGL6′, RGL7′, and RGL8′ may be alternately disposed in different layers, thereby a size of the area disposed in the second direction D2 may be reduced.

However, embodiments of the disclosure are not limited thereto. The first, second, third, fourth, fifth, sixth, seventh, and eighth bypass gate lines RGL1′, RGL2′, RGL3′, RGL4′, RGL5′, RGL6′, RGL7′, and RGL8′ may be freely disposed to alternate with each other on the first insulating layer IL1 and the fourth insulating layer IL4. The first, second, third, fourth, fifth, sixth, seventh, and eighth bypass gate lines RGL1′, RGL2′, RGL3′, RGL4′, RGL5′, RGL6′, RGL7′, and RGL8′ may be disposed in insulating layers other than the first insulating layer IL1 and the fourth insulating layer IL4.

The driving voltage line DVL′ may be disposed on the second insulating layer IL2. The driving voltage line DVL′ may transmit the driving voltage (e.g., the driving voltage ELVDD in FIG. 15). The driving voltage line DVL′ may transmit the driving voltage to the pixels (e.g., pixels PX′ of FIG. 11).

In an embodiment, the driving voltage line DVL′ may overlap the first, second, third, fourth, fifth, sixth, seventh, and eighth bypass gate lines RGL1′, RGL2′, RGL3′, RGLA′, RGL5′, RGL6′, RGL7′, and RGL8′ in a plan view. The driving voltage line DVL′ may prevent a coupling effect between the first, second, third, and fourth bypass gate lines RGL1′, RGL2′, RGL3′, and RGL4′ and the fifth, sixth, seventh, and eighth bypass data lines RGL5′, RGL6′, RGL7′, and RGL8′ by disposing between the first, second, third, and fourth bypass gate lines RGL1′, RGL2′, RGL3′, and RGL4′ and the fifth, sixth, seventh, and eighth bypass data lines RGL5′, RGL6′, RGL7′, and RGL8′ in a cross-sectional view.

The first and second bypass data lines RDL1′ and RDL2′ may be disposed on the via layer VIA. For example, the first and second bypass data lines RDL1′ and RDL2′ may be disposed on a same layer. In another embodiment, the first and second bypass data lines RDL1′ and RDL2′ may be disposed on the first, second, third, fourth, fifth, sixth, seventh, and eighth bypass gate lines RGL1′, RGL2′, RGL3′, RGL4′, RGL5′, RGL6′, RGL7′, and RGL8′ in a cross-sectional view.

The first and second bypass data lines RDL1′ and RDL2′ may transmit data signals to the pixels (e.g., the pixels PX′ of FIG. 11). Each of the first bypass data line RDL1′ and the second bypass data line RDL2′ may apply data to the pixels PX′ disposed in two columns, as shown in FIG. 11.

As a result, as the first, second, third, fourth, fifth, sixth, seventh, and eighth bypass gate lines RGL1′, RGL2′, RGL3′, RGL4′, RGL5′, RGL6′, RGL7′, and RGL8′ are alternately disposed on different layers in the first peripheral area SA1′, a size of the first peripheral area SA1′ may be reduced. Simply put, if the first, second, third, fourth, fifth, sixth, seventh, and eighth bypass gate lines RGL1′, RGL2′, RGL3′, RGL4′, RGL5′, RGL6′, RGL7′, and RGL8′ were disposed on a same layer, a wide area extending in the second direction D2 was required, the area in the second direction D2 may be reduced by alternating arrangement on different layers, thereby reducing the size of the first peripheral area SA1′.

Accordingly, a planar size of the surrounding area surrounding the hole area in the display device may be reduced, and the user may efficiently use a wider screen when using the display device.

The disclosure may be applied to a display device and an electronic device including a same. For example, the disclosure may be applied to high-resolution smartphones, mobile phones, smart pads, smart watches, tablet PCs, vehicle navigation systems, televisions, computer monitors, laptops, etc.

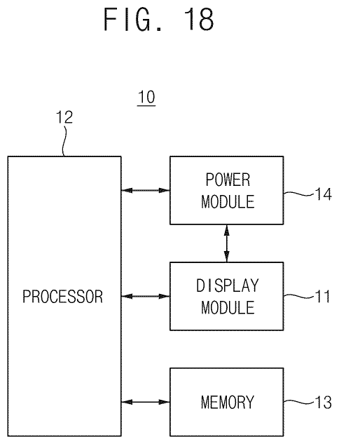

FIG. 18 is block-diagram for showing an electronic device according to an embodiment of the disclosure.

Referring to FIG. 1 and FIG. 18, the display device DD according to the embodiments of present disclosure may be applied to various electronic devices 10. The electronic device 10 according to an embodiment may include the display device DD, and may further include a module or device including additional functions in addition to the display device DD.

The electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information necessary for an operation of the processor 12 or the display module 11. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device, and a power conversion module that converts a power supplied by the power supply module to generate power necessary for an operation of the electronic device 10.

At least one of the components of the electronic device 10 described above may be included in the display device according to the embodiments described above. In addition, some of individual modules functionally included in one module may be included in the display device, and other parts may be provided separately from the display device. For example, the display device DD may include the display module 11, and the processor 12, the memory 13, and the power module 14 may be provided in the form of other devices within the electronic device 10 other than the display device DD.

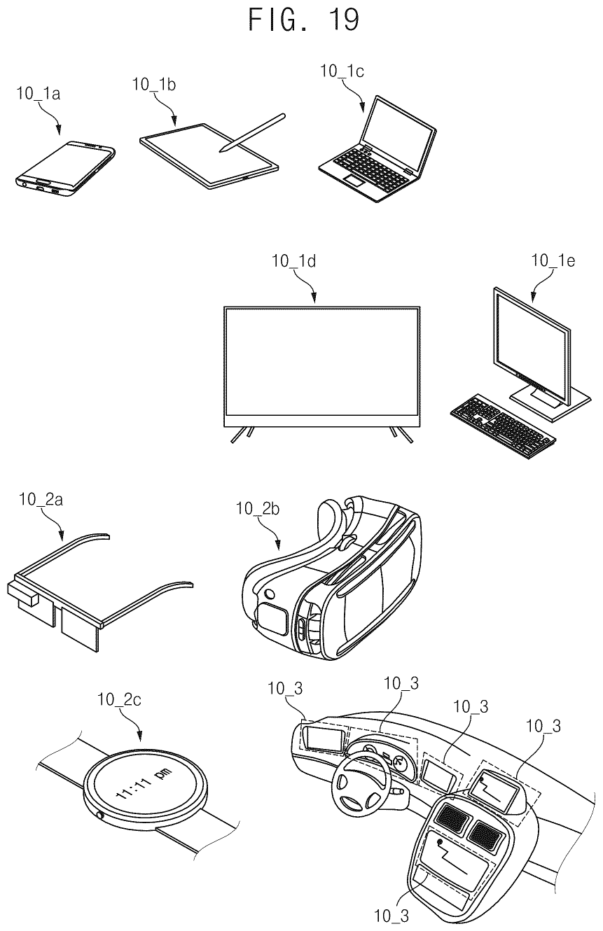

FIG. 19 is schematic views for showing the electronic device according to various embodiments of FIG. 18.

Referring to FIG. 18 and FIG. 19, various electronic devices to which the display device DD according to embodiments is applied may include not only image display electronic devices such as a smart phone 10_1a, a tablet PC 10_1b, a laptop 10_1c, a TV 10_1d, and a desk monitor 10_1e, but also wearable electronic devices including display modules such as smart glasses 10_2a, a head-mounted display 10_2b, and a smart watch 10_2c, and vehicle electronic devices 10_3 including display modules such as a CID (center information display) and a room mirror display placed on a dashboard, center fascia, or dashboard of an automobile.

However, this is exemplary, and the electronic device 10 according to embodiments of the present disclosure is not limited thereto. For example, the electronic device 10 may be implemented as a mobile phone, a video phone, a smart pad, a smart watch, a tablet PC, a vehicle display, a computer monitor, a notebook computer, a head-mounted display device, etc. In addition, the electronic device 10 may be a television, a monitor, a notebook computer, or a tablet. In addition, the electronic device 10 may be an automobile.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a plurality of data lines disposed in a display area and extending in a first direction;
a plurality of gate lines disposed in the display area and extending in a second direction intersecting the first direction;
a plurality of bypass data lines electrically connected to the plurality of data lines and disposed in a first peripheral area adjacent to the display area; and
a plurality of bypass gate lines electrically connected to the plurality of gate lines, disposed in the first peripheral area, and alternately disposed in at least two layers.

2. The display device of claim 1, wherein
the display area includes:
a first pixel;
a second pixel spaced apart from the first pixel in the second direction;
a third pixel spaced apart from the first pixel in a direction opposite to the first direction; and
a fourth pixel spaced apart from the third pixel in the second direction, and the plurality of gate lines include:
a first gate line electrically connected to the first pixel and extending in the second direction;
a second gate line electrically connected to the second pixel and extending in the second direction;
a third gate line electrically connected to the third pixel and extending in the second direction;
a fourth gate line electrically connected to the fourth pixel and extending in the second direction;
a fifth gate line electrically connected to the first, second, third, and fourth pixels and extending in the second direction; and
a sixth gate line electrically connected to the first, second, third, and fourth pixels and extending in the second direction.

3. The display device of claim 2, wherein
the plurality of bypass gate lines include a first, a second, a third, a fourth, a fifth, and a sixth bypass gate lines electrically connected to the first, second, third, fourth, fifth, and sixth gate lines respectively and disposed in the first peripheral area, and
the first, second, fifth, third, fourth, and sixth bypass gate lines are alternately disposed in the at least two layers.

4. The display device of claim 3, wherein the first, fourth, and fifth bypass gate lines and the second, third, and sixth bypass gate lines are disposed on different layers.

5. The display device of claim 4, wherein the first gate line is spaced apart from the fifth gate line by a gap in a range of about 2 um to about 3.5 um.

6. The display device of claim 2, wherein one of the plurality of data lines is electrically connected to the first, second, third, and fourth pixels.

7. The display device of claim 2, further comprising:
a first gate driver electrically connected to the first and third gate lines;
a second gate driver electrically connected to the second and fourth gate lines;
a third gate driver electrically connected to the fifth gate line; and
a fourth gate driver electrically connected to the sixth gate line, wherein
the first and third gate drivers are disposed on a side of a second peripheral area, and
the second and fourth gate drivers are disposed on another side of the second peripheral area to be spaced apart from the side of the second peripheral area in the second direction with the display area interposed between the side and the another side of the second peripheral area.

8. The display device of claim 1, wherein the plurality of bypass data lines are disposed on the plurality of bypass gate lines.

9. The display device of claim 1, wherein the plurality of bypass data lines are disposed on a same layer.

10. The display device of claim 1, further comprising:
a driving voltage line disposed between the plurality of bypass data lines and the plurality of bypass gate lines in a cross-sectional view,
wherein the driving voltage line overlaps the plurality of bypass gate lines in a plan view.

11. The display device of claim 1, wherein the first peripheral area is disposed between the display area and a hole area.

12. The display device of claim 1, wherein
the display area includes:
a first pixel;
a second pixel spaced apart from the first pixel in the second direction;
a third pixel spaced apart from the first pixel in a direction opposite to the first direction; and
a fourth pixel spaced apart from the third pixel in the second direction, and the plurality of gate lines include:
a first gate line electrically connected to the first pixel and extending in the second direction;
a second gate line electrically connected to the second pixel and extending in the second direction;
a third gate line electrically connected to the third pixel and extending in the second direction;
a fourth gate line electrically connected to the fourth pixel and extending in the second direction;
a fifth gate line electrically connected to the first, second, third, and fourth pixels and extending in the second direction;
a sixth gate line electrically connected to the first, second, third, and fourth pixels and extending in the second direction;
a seventh gate line electrically connected to the first, second, third, and fourth pixels and extending in the second direction; and
an eighth gate line electrically connected to the first, second, third, and fourth pixels and extending in the second direction.

13. The display device of claim 12, wherein
the plurality of bypass gate lines include a first, a second, a third, a fourth, a fifth, a sixth, a seventh, and a eighth bypass gate lines electrically connected to the first, second, third, fourth, fifth, sixth, seventh, and eighth gate lines respectively and disposed in the first peripheral area, and
the first, fifth, second, sixth, third, seventh, fourth, and eighth bypass gate lines are alternately disposed in the at least two layers.

14. The display device of claim 13, wherein the first, second, third, and fourth gate lines and the fifth, sixth, seventh, and eighth gate lines are alternately disposed on different layers.

15. The display device of claim 14, wherein the first gate line is spaced apart from the second gate line by a gap in a range of about 2 um to about 3.5 um.

16. The display device of claim 12, wherein one of the plurality of data lines is electrically connected to the first, second, third, and fourth pixels.

17. The display device of claim 12, further comprising:
a first gate driver electrically connected to the first and third gate lines;
a second gate driver electrically connected to the second and fourth gate lines;
a third gate driver electrically connected to the fifth gate line;
a fourth gate driver electrically connected to the sixth gate line;
a fifth gate driver electrically connected to the seventh gate line; and
a sixth gate driver electrically connected to the eighth gate line, wherein
the first, third, and fifth gate drivers are disposed on a side of a second peripheral area, and
the second, fourth, and sixth gate drivers are disposed on another side of the second peripheral area to be spaced apart from the side of the second peripheral area in the second direction with the display area interposed between the side and the another side of the second peripheral area.

18. The display device of claim 12, wherein the plurality of bypass data lines are disposed on the plurality of bypass gate lines.

19. The display device of claim 12, wherein the plurality of bypass data lines are disposed on a same layer.

20. The display device of claim 12, further comprising:
a driving voltage line disposed between the plurality of bypass data lines and the plurality of bypass gate lines in a cross-sectional view,
wherein the driving voltage line overlaps the plurality of bypass gate lines in a plan view.

21. An electronic device comprising:
a display device; and
a processor configured to drive the display device, and
wherein the display device includes:
a plurality of data lines disposed in a display area and extending in a first direction;
a plurality of gate lines disposed in the display area and extending in a second direction intersecting the first direction;
a plurality of bypass data lines electrically connected to the plurality of data lines and disposed in a first peripheral area adjacent to the display area; and
a plurality of bypass gate lines electrically connected to the plurality of gate lines, disposed in the first peripheral area, and alternately disposed in at least two layers.
